(19) United States
(12) Patent Application Publication
(10) Pub. No.: US 2026/0173434 A1
(43) Pub. Date: Jun. 18, 2026

(54) INTEGRATED CIRCUIT DEVICE

(71) Applicant: Samsung Electronics Co., Ltd., Suwon-si (KR)

(72) Inventors: Soyeong Ahn, Suwon-si (KR); Bong Jin Kuh, Suwon-si (KR); Suk Yang, Suwon-si (KR); Sangmoon Lee, Suwon-si (KR)

(21) Appl. No.: 19/321,017

(22) Filed: Sep. 5, 2025

(30) Foreign Application Priority Data
Dec. 18, 2024 (KR) 10-2024-0190461
Jan. 8, 2025 (KR) 10-2025-0002879

(51) Int. Cl. H10D 30/47; H10D 30/00; H10D 30/01

(52) U.S. Cl. CPC H10D 30/481; H10D 30/017; H10D 30/019; H10D 30/501

(57) ABSTRACT

An example integrated circuit device includes an active region extending in a first horizontal direction on a substrate, a channel layer arranged on the active region to be apart in a vertical direction and extending in the first horizontal direction, a gate line extending in a second horizontal direction intersecting the first horizontal direction on the active region and surrounding the channel layer, a source/drain region arranged on the active region in contact with the channel layer, and an oxide layer arranged between the channel layer and the gate line. The channel layer comprises transition metal dichalcogenides (TMD), and the oxide layer comprises high dielectric constant (high-k) oxide.

### CROSS-REFERENCE TO RELATED APPLICATIONS

This application claims priority under 35 U.S.C. § 119 to Korean Patent Application No. 10-2024-0190461, filed on Dec. 18, 2024, and 35 U.S.C. § 119 to Korean Patent Application No. 10-2025-0002879, filed on Jan. 8, 2025, in the Korean Intellectual Property Office, the disclosures of which are incorporated by reference herein in their entireties.

### BACKGROUND

As down-scaling of integrated circuit devices is rapidly progressing, it is necessary to secure not only a fast operation speed but also operation accuracy due to increased leakage current in integrated circuit devices. Accordingly, various studies are being conducted to provide integrated circuit devices with structures that may reduce leakage current and improve reliability.

### SUMMARY

The present disclosure relates to an integrated circuit device with a high dielectric constant oxide layer at an interface of a channel layer and a gate line.

In general, according to some aspects, an integrated circuit device includes an active region extending in a first horizontal direction on a substrate, a channel layer arranged on the active region to be apart in a vertical direction and extending in the first horizontal direction, a gate line extending in a second horizontal direction intersecting the first horizontal direction on the active region and surrounding the channel layer, a source/drain region arranged on the active region in contact with the channel layer, and an oxide layer arranged between the channel layer and the gate line. The channel layer includes transition metal dichalcogenides (TMD), and the oxide layer includes high dielectric constant (high-k) oxide.

In general, according to some aspects, an integrated circuit device includes an active region extending in a first horizontal direction on a substrate, a channel layer including a first channel layer arranged on the active region to be apart in a vertical direction and extending in the first horizontal direction and a second channel layer covering top and bottom surfaces of the first channel layer, a gate line extending in a second horizontal direction intersecting the first horizontal direction on the active region and surrounding the channel layer, a source/drain region arranged on the active region in contact with the channel layer, and an oxide layer arranged between the channel layer and the gate line. The first channel layer includes transition metal dichalcogenides (TMD) including a first transition metal. The second channel layer includes transition metal dichalcogenides (TMD) including a second transition metal that is different from the first transition metal. The oxide layer includes high dielectric constant (high-k) oxide.

In general, according to some aspects, an integrated circuit device includes an active region extending in a first horizontal direction on a substrate, a channel layer arranged on the active region to be apart in a vertical direction and extending in the first horizontal direction, a gate line extending in a second horizontal direction intersecting the first horizontal direction on the active region and surrounding the channel layer, which includes sub-gates between the channel layers adjacent in the vertical direction and between a lowermost channel layer and the active region and a main gate connected to the sub-gates and covering the uppermost channel layer, a source/drain region arranged on the active region in contact with the channel layer, an internal spacer between the sub-gate and the source/drain region, and an oxide layer arranged between the channel layer and the gate line. The channel layer includes transition metal dichalcogenides (TMD) including a first transition metal, and the oxide layer includes high dielectric constant (high-k) oxide including the first transition metal.

### BRIEF DESCRIPTION OF THE DRAWINGS

Implementations will be more clearly understood from the following detailed description taken in conjunction with the accompanying drawings.

FIG. 1 is a layout for describing an example of an integrated circuit device

FIG. 2A is an example cross-sectional view taken along the line X1-X1′ of FIG. 1.

FIG. 2B is an example cross-sectional view taken along the line Y2-Y2′ of FIG. 1.

FIG. 3 is an enlarged cross-sectional view of an example of a region indicated by “EX1” of FIG. 2.

FIG. 4 is an example cross-sectional view taken along the line Y1-Y1′ of FIG. 1.

FIG. 5 is a view illustrating an example of a region corresponding to a cross-section taken along the line X1-X1′ of FIG. 1, and is a cross-sectional view for describing an example of an integrated circuit device.

FIG. 6 is an enlarged cross-sectional view of an example of a region EX2 of FIG. 5.

FIGS. 7, 8, 9, 10, 11, 12, 13, 14, 15, 16, and 17 are cross-sectional views illustrating an example of a method of manufacturing an integrated circuit device.

### DETAILED DESCRIPTION

Hereinafter, implementations of the present disclosure will be described in detail with reference to the accompanying drawings. Like reference numerals refer to like elements, and their repetitive descriptions are omitted.

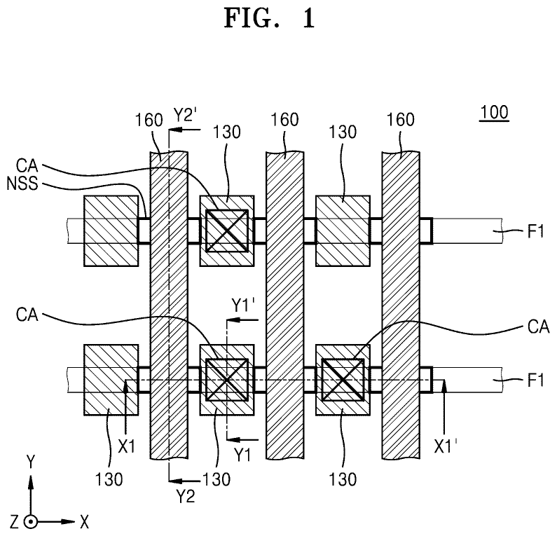

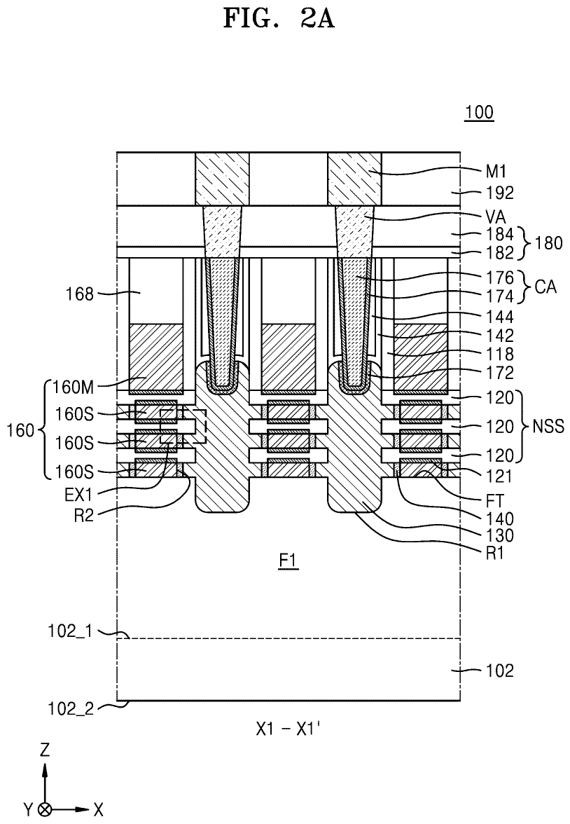

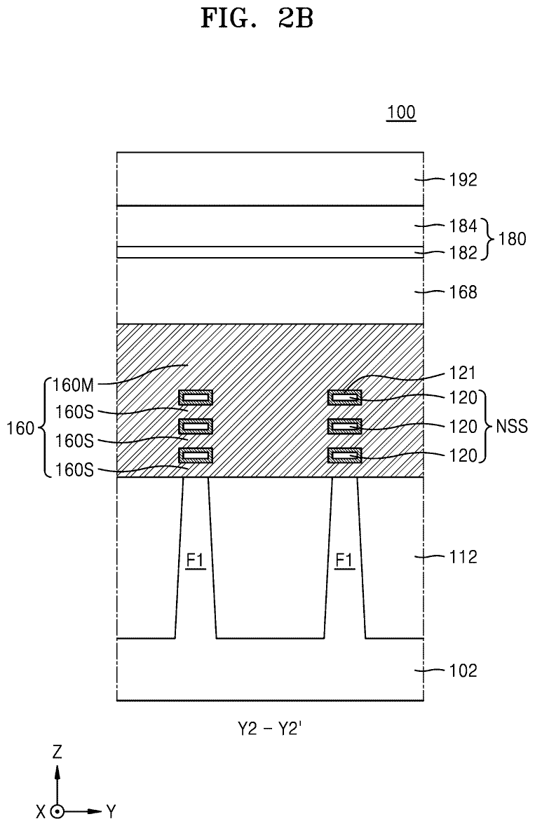

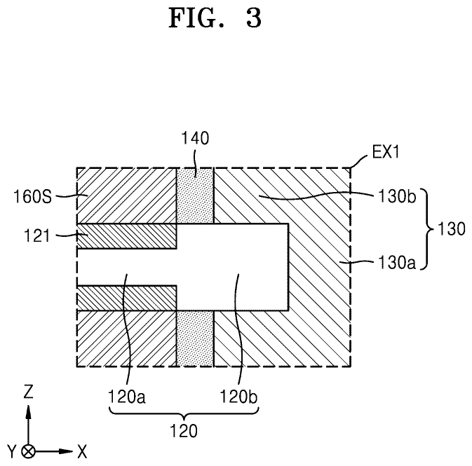

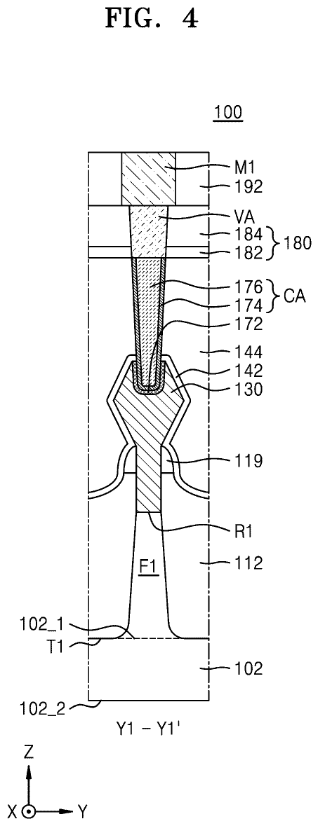

FIG. 1 is a layout for describing an example of an integrated circuit device 100. FIG. 2A is an example cross-sectional view taken along the line X1-X1′ of FIG. 1. FIG. 2B is an example cross-sectional view taken along the line Y2-Y2′ of FIG. 1. FIG. 3 is an enlarged cross-sectional view of an example of a region EX1 of FIG. 2. FIG. 4 is an example cross-sectional view taken along the line Y1-Y1′ of FIG. 1.

Referring to FIGS. 1 to 4, the integrated circuit device 100 including a nanowire or nanosheet-shaped active region and a field effect transistor (FET) having a gate-all-around structure including a gate surrounding the active region will be described. For example, the integrated circuit device 100 may include a multi-bridge channel FET (MBCFET) device. However, the present disclosure is not limited thereto, and the integrated circuit device 100 may include a planar FET device or a finFET device.

In some implementations, the integrated circuit device 100 of the present disclosure may include a plurality of active regions F1 protruding from a substrate 102 to define trench regions T1 on the substrate 102. The plurality of active regions F1 may extend in parallel to one another in a first horizontal direction (X direction) on the substrate 102 and may be apart from one another in a second horizontal direction (Y direction).

In some implementations, the substrate 102 may include a semiconductor such as silicon (Si) or germanium (Ge), or a compound semiconductor such as SiGe, SiC, GaAs, InAs, InGaAs, or InP. The terms “SiGe”, “SiC”, “GaAs”, “InAs”, “InGaAs”, and “InP” used in the current specification refer to materials including elements included in each term, and are not chemical formulas representing stoichiometric relationships. The substrate 102 may include a conductive region, for example, an impurity-doped well, or an impurity-doped structure.

In some implementations, a device isolation layer 112 may be arranged in the trench region T1 defining the active region F1. The device isolation layer 112 may cover part of a sidewall of the active region F1 in the trench region T1 and may be apart from the substrate 102 in a vertical direction (Z direction). The device isolation layer 112 may include a silicon oxide layer.

In some implementations, a plurality of gate lines 160 may be arranged on the active region F1. Each of the plurality of gate lines 160 may extend in the second horizontal direction (Y direction). A plurality of nanosheet stacks NSS may be arranged on a fin top surface FT of the active region F1 in regions in which the active region F1 and the plurality of gate lines 160 intersect. Each of the plurality of nanosheet stacks NSS may include at least one nanosheet facing the fin top surface FT at a position apart from the fin top surface FT of the active region F1 in the vertical direction (Z direction). The term “nanosheet” used in the current specification refers to a conductive structure having a cross-section substantially perpendicular to a direction in which current flows. The nanosheet should be understood as including nanowires.

In some implementations, each of the plurality of nanosheet stacks NSS may include a plurality of channel layers 120 overlapping one another in the vertical direction (Z direction) on the active region F1. Vertical distances (Z direction) from the fin top surface FT of the active region F1 to the plurality of channel layers 120 may be different. Each of the plurality of gate lines 160 may surround the channel layer 120 included in the nanosheet stack NSS overlapping in the vertical direction (Z direction).

Although it is illustrated in FIG. 1 that a planar shape of the nanosheet stack NSS is approximately square, the present disclosure is not limited thereto. The nanosheet stack NSS may have various planar shapes according to a planar shape of each of the active region F1 and the gate line 160. In the current example, the plurality of nanosheet stacks NSS and the plurality of gate lines 160 are arranged on one active region F1, and the plurality of nanosheet stacks NSS are arranged in a line in the first horizontal direction (X direction) on one active region F1. However, the number of nanosheet stacks NSS and gate lines 160 arranged on one active region F1 is not particularly limited.

In some implementations, each of the plurality of channel layers 120 may have a thickness selected in a range of about 4 nm to about 6 nm. However, the present disclosure is not limited thereto. At this time, the thickness of each of the plurality of channel layers 120 refers to a size in the vertical direction (Z direction). In some implementations, the plurality of channel layers 120 may have substantially the same thickness in the vertical direction (Z direction). In some implementations, at least some of the plurality of channel layers 120 may have different thicknesses in the vertical direction (Z direction).

In some implementations, the plurality of channel layers 120 included in one nanosheet stack NSS may have the same or similar sizes in the first horizontal direction (X direction). In some implementations, unlike the example illustrated in FIG. 2A, at least some of the plurality of channel layers 120 included in one nanosheet stack NSS may have different sizes in the first horizontal direction (X direction). Although it is illustrated in FIG. 2A that each of the plurality of nanosheet stacks NSS includes three channel layers 120, the present disclosure is not limited thereto. For example, the nanosheet stack NSS may include at least one channel layer, and the number of channel layers constituting the nanosheet stack NSS is not particularly limited.

In some implementations, the plurality of channel layers 120 may include a two-dimensional semiconductor material. At this time, the two-dimensional material may refer to a material having a layered structure in which constituent atoms are two-dimensionally bonded. Two-dimensional materials with semiconductor properties have excellent electrical properties and may maintain high mobility without significantly changing their properties even when the thickness is reduced to nano-scale. For example, the plurality of channel layers 120 may include transition metal dichalcogenides (TMD).

In some implementations, TMD as a two-dimensional material with semiconductor properties may refer to a compound of a transition metal and a chalcogen element. At this time, the transition metal may include, for example, at least one of molybdenum (Mo), tungsten (W), niobium (Nb), vanadium (V), tantalum (Ta), titanium (Ti), zirconium (Zr), hafnium (Hf), cobalt (Co), technetium (Tc), and rhenium (Re), and the chalcogen element may include, for example, at least one of sulfur (S), selenium (Se), and tellurium (Te). As a specific example, the TMD may include MoS₂, MoSe₂, MoTe₂, WS₂, WSe₂, WTe₂, ZrS₂, ZrSe₂, HfS₂, HfSe₂, NbSe₂, and ReSe₂. Ho wever, the present disclosure is not limited thereto.

In some implementations, each of the plurality of channel layers 120 may include a channel portion 120a and an extension portion 120b. The channel portion 120a may extend in the first horizontal direction (X direction) and may be surrounded by the gate line 160. The extension portion 120b may extend from both ends of the channel portion 120a in the first horizontal direction (X direction) to be in contact with a source/drain region 130.

In some implementations, an oxide layer 121 may be between the plurality of channel layers 120 and the gate line 160. The oxide layer 121 may be formed at an interface between the plurality of channel layers 120 and the gate line 160. Specifically, the oxide layer 121 may be between the channel portion 120a of the channel layer 120 and the gate line 160. The oxide layer 121 may surround the channel portion 120a. The oxide layer 121 may surround all sides of the channel portion 120a. For example, the oxide layer 121 may cover top and bottom surfaces and sidewalls in the second horizontal direction (Y direction) of the channel portion 120a, and may extend in the first horizontal direction (X direction).

In some implementations, one surface of the oxide layer 121 may be in contact with the gate line 160, and the other surface opposite to the one surface may be in contact with the channel portion 120a of the channel layer 120. For example, in the case of the oxide layer 121 arranged on a top surface of the channel portion 120a, a top surface may be in contact with the gate line 160 and a bottom surface may be in contact with the channel portion 120a. In addition, in the case of the oxide layer 121 arranged on a bottom surface of the channel portion 120a, a bottom surface may be in contact with the gate line 160 and a top surface may be in contact with the channel portion 120a.

In some implementations, an interface between the gate line 160 and the oxide layer 121 may be coplanar with one surface of the extension portion 120b. For example, in the case of the oxide layer 121 arranged on the top surface of the channel portion 120a, the interface between the gate line 160 and the oxide layer 121 may be coplanar with a top surface of the extension portion 120b. In addition, in the case of the oxide layer 121 arranged on the bottom surface of the channel portion 120a, the interface between the gate line 160 and the oxide layer 121 may be coplanar with a bottom surface of the extension portion 120b.

In some implementations, a thickness of the channel portion 120a in the vertical direction (Z direction) may be less than a thickness of the extension portion 120b in the vertical direction (Z direction). At this time, the sum of the thicknesses in the vertical direction (Z direction) of the channel portion 120a and the oxide layer 121 in contact with the channel portion 120a may be substantially equal to the thickness of the extension portion 120b in vertical direction (Z direction). In addition, a width of the channel portion 120a in the second horizontal direction (Y direction) may be less than a width of the extension portion 120b in the second horizontal direction (Y direction). At this time, the sum of the widths in the second horizontal direction (Y direction) of the channel portion 120a and the oxide layer 121 in contact with the channel 120a may be substantially equal to the width of the extension 120b in second horizontal direction (Y direction).

In some implementations, the oxide layer 121 may include high dielectric constant (high-k) oxide. For example, the oxide layer 121 may include oxide including the same transition metal as the channel layer 120. For example, when the channel layer 120 includes hafnium disulfide (HfS₂), the oxide layer 121 may include hafnium dioxide (HfO₂). However, the present disclosure is not limited thereto. At this time, the channel 120a and the extension 120b of the channel layer 120 may include the same material. For example, the channel 120a and the extension 120b may include HfS₂.

In some implementations, the channel layer 120 may have a monolayer or multilayer structure, wherein each layer may have an atomic level thickness.

In the case of an integrated circuit device according to a comparative example, an insulating layer may be formed between the gate line and an internal spacer. In addition, in the integrated circuit device 100 of the present disclosure, the oxide layer 121 may be formed only at the interface between the channel layer 120 and the gate line 160, thereby reducing the area of an unnecessary insulating layer and thereby reducing parasitic capacitance.

In addition, in the case of the integrated circuit device according to the comparative example, there is a problem that a surface of TMD needs to be denatured in order to form an insulating layer on the surface of TMD. In an integrated circuit device manufacturing method according to the present disclosure, the interface between the oxide layer 121 and the channel layer 120 may be formed uniformly by forming the oxide layer 121 on a surface of the channel layer 120 by an oxidation process. Accordingly, electrical characteristics of the integrated circuit device 100 may be improved.

In some implementations, each of the plurality of gate lines 160 may include a main gate 160M and a plurality of sub-gates 160S. The main gate 160M may cover a top surface of the nanosheet stack NSS and may extend in the second horizontal direction (Y direction). The plurality of sub-gates 160S may be integrally connected to the main gate 160M, and may be arranged among the plurality of channel layers 120, respectively, and between the lowermost channel layer 120 and the active region F1. In the vertical direction (Z direction), a thickness of each of the plurality of sub-gates 160S may be less than a thickness of the main gate 160M.

In some implementations, each of the plurality of gate lines 160 may include a metal, metal nitride, metal carbide, or a combination thereof. The metal may be selected from Ti, W, ruthenium (Ru), Nb, Mo, Hf, nickel (Ni), Co, platinum (Pt), ytterbium (Yb), terbium (Tb), dysprosium (Dy), erbium (Er), and palladium (Pd). The metal nitride may be selected from TiN and TaN. The metal carbide may include TiAlC. However, the material constituting the plurality of gate lines 160 is not limited thereto.

In some implementations, a plurality of active region recesses R1 may be formed in the active region F1. A vertical level of the lowermost surface of each of the plurality of active region recesses R1 may be lower than a vertical level of the fin top surface FT of the active region F1.

In some implementations, the plurality of source/drain regions 130 may be arranged among the plurality of gate lines 160, respectively. Each of the plurality of source/drain regions 130 may be arranged adjacent to at least one gate line 160 selected from the plurality of gate lines 160. Each of the plurality of source/drain regions 130 may have surfaces facing an adjacent channel layer 120.

In some implementations, a plurality of internal spacers 140 may be between the plurality of sub-gates 160S and the plurality of source/drain regions 130, respectively. One sidewall of the internal spacer 140 may be in contact with the sub-gate 160S, and the other sidewall opposite to the one sidewall may be in contact with the source/drain region 130. In addition, top and bottom surfaces of the internal spacer 140 may each be in contact with the extension 120b of the channel layer 120. The plurality of internal spacers 140 may cover sidewalls in the first horizontal direction (X direction) of the sub-gate 160S. Specifically, the pair of internal spacers 140 may be apart from each other in the first horizontal direction (X direction) with the sub-gate 160S therebetween. At this time, the internal spacer 140 may include silicon nitride, silicon oxide, SiCN, SiBN, SiON, SiOCN, SiBCN, SiOC, or a combination thereof.

In some implementations, each of the plurality of source/drain regions 130 may include a central portion 130a and a protrusion 130b. The central portion 130a may be in contact with the surface of each of the plurality of channel layers 120 included in each of the plurality of nanosheet stacks NSS. Specifically, the central portion 130a may be in contact with a sidewall of the extension 120b of the channel layer 120. The protrusion 130b may extend from the central portion 130a toward the sub-gate 160S. Specifically, the protrusion 130b may be in contact with the sidewall of the internal spacer 140. The protrusion 130b may be apart from the sub-gate 160S with the internal spacer 140 therebetween.

In some implementations, a sidewall of the central portion 130a in contact with the extension 120b of the channel layer 120 and a sidewall of the protrusion 130b in contact with the internal spacer 140 may be arranged on different planes. The plurality of protrusions 130b may overlap the plurality of sub-gates 160S in the first horizontal direction (X direction). In addition, top and bottom surfaces of the plurality of protrusions 130b may be in contact with top and bottom surfaces of the plurality of extensions 120b, respectively. The plurality of protrusions 130b and the plurality of extensions 120b may overlap in the vertical direction (Z direction).

In some implementations, each of the plurality of source/drain regions 130 may include an epitaxially grown semiconductor layer. In some implementations, each of the plurality of source/drain regions 130 may include an epitaxially grown Si layer, an epitaxially grown SiC layer, or a plurality of epitaxially grown SiGe layers. When the source/drain region 130 constitutes an n-channel metal-oxide-semiconductor field-effect transistor (MOSFET) (NMOS) transistor, the source/drain region 130 may include a Si layer doped with an n-type dopant or a SiC layer doped with an n-type dopant. The n-type dopant may be selected from phosphorus (P), arsenic (As), and antimony (Sb). When the source/drain region 130 constitutes a p-channel MOSFET (PMOS) transistor, the source/drain region 130 may include a SiGe layer doped with a p-type dopant. The p-type dopant may be selected from boron (B) and gallium (Ga).

In some implementations, the plurality of nanosheet stacks NSS may be arranged on the fin top surfaces FT of the plurality of active regions F1 in regions in which the plurality of active regions F1 and the plurality of gate lines 160 intersect, respectively, and a plurality of FETs may be formed at portions at which the plurality of active regions F1 and the plurality of gate lines 160 intersect, respectively, on the substrate 102.

In some implementations, a capping insulation pattern 168 may be arranged on the gate line 160. Specifically, the capping insulation pattern 168 may cover a top surface of the main gate 160M. The capping insulation pattern 168 may include a silicon nitride layer or a silicon oxide layer.

In some implementations, both sidewalls of each of the gate line 160 and the capping insulation pattern 168 may be covered with a first insulating spacer 118. Specifically, the first insulating spacer 118 may cover both sidewalls of the main gate 160M on the top surface of each of the plurality of nanosheet stacks NSS. The first insulating spacer 118 may be in contact with the both sidewalls of each of the gate line 160 and the capping insulation pattern 168.

In some implementations, a plurality of second insulating spacers 119 each covering one sidewall of the source/drain region 130 and the other sidewall facing the one sidewall may be arranged on a top surface of the device isolation layer 112. In some implementations, each of the plurality of second insulating spacers 119 may be integrally connected to an adjacent first insulating spacer 118. In some implementations, at least some of the plurality of second insulating spacers 119 may be omitted.

In some implementations, each of the plurality of first insulating spacers 118 and the plurality of second insulating spacers 119 may include silicon nitride, silicon oxide, SiCN, SiBN, SiON, SiOCN, SiBCN, SiOC, or a combination thereof. The terms “SiCN”, “SiBN”, “SiON”, “SiOCN”, “SiBCN”, and “SiOC” used in the current specification refer to materials including elements included in each term, and are not chemical formulas representing stoichiometric relationships.

In some implementations, a metal silicide layer 172 may be arranged on a top surface of each of the plurality of source/drain regions 130. The metal silicide layer 172 may include a metal including Ti, W, Ru, Nb, Mo, Hf, Ni, Co, Pt, Yb, Tb, Dy, Er, or Pd. For example, the metal silicide layer 172 may include titanium silicide. However, the present disclosure is not limited thereto.

In some implementations, an insulating liner 142 and an inter-gate insulating layer 144 may be sequentially arranged on the plurality of source/drain regions 130 and the plurality of metal silicide layers 172. The first insulating spacer 118 and the plurality of source/drain regions 130 may be covered with the insulating liner 142. In some implementations, the insulating liner 142 may include SiN, SiCN, SiBN, SiON, SiOCN, SiBCN, or a combination thereof. However, the present disclosure is not limited thereto. The inter-gate insulating layer 144 may include a silicon oxide layer. However, the present disclosure is not limited thereto.

In some implementations, a plurality of source/drain contacts CA may be arranged on the plurality of source/drain regions 130, respectively. Each of the plurality of source/drain contacts CA may penetrate the insulating liner 142 and the inter-gate insulating layer 144 in the vertical direction (Z direction), and may be electrically connected to at least one source/drain region 130 selected from the plurality of source/drain regions 130. Each of the plurality of source/drain contacts CA may be in contact with the metal silicide layer 172 formed on the source/drain region 130. Each of the plurality of source/drain contacts CA may be electrically connected to the source/drain region 130 through the metal silicide layer 172. Each of the plurality of source/drain contacts CA may be apart from the main gate 160M of the gate line 160 in the first horizontal direction (X direction) with the first insulating spacer 118 therebetween.

In some implementations, each of the plurality of source/drain contacts CA may include a conductive barrier layer 174 and a contact plug 176. A bottom surface and a sidewall of the contact plug 176 may be covered with the conductive barrier layer 174. The conductive barrier layer 174 may include a metal or conductive metal nitride. For example, the conductive barrier layer 174 may include Ti, Ta, W, TiN, TaN, WN, WCN, TiSiN, TaSiN, WSiN, or a combination thereof. However, the present disclosure is not limited thereto. The contact plug 176 may include Mo, W, Co, Ru, manganese (Mn), Ti, Ta, Al, Cu, a combination thereof, or an alloy thereof. However, the present disclosure is not limited thereto. In some implementations, the conductive barrier layer 174 may be omitted from each of the plurality of source/drain contacts CA.

In some implementations, a top surface of each of the source/drain contact CA, the capping insulation pattern 168, the insulating liner 142, and the inter-gate insulating layer 144 may be covered with an upper insulating structure 180. The upper insulating structure 180 may include an etch stop layer 182 and an interlayer insulating layer 184 sequentially stacked on each of the plurality of source/drain contacts CA, the plurality of capping insulation patterns 168, and the inter-gate insulating layer 144. The etch stop layer 182 may include SiC, SiN, nitrogen-doped silicon carbide (SiC:N), SiOC, AlN, AlON, AlO, AlOC, or a combination thereof. The interlayer insulating layer 184 may include an oxide layer, a nitride layer, an ultra-low k (ULK) layer having an ultra low dielectric constant K of about 2.2 to about 2.4, or a combination thereof. For example, the interlayer insulating layer 184 may include a tetraethylorthosilicate (TEOS) layer, a high-density plasma (HDP) oxide layer, a boro-phospho-silicate glass (BPSG) layer, a flowable chemical vapor deposition (FCVD) oxide layer, a SiON layer, a SiN layer, a SiOC layer, a SiCOH layer, or a combination thereof. However, the present disclosure is not limited thereto.

In some implementations, a plurality of source/drain via contacts VA may be arranged on the plurality of source/drain contacts CA, respectively. Each of the plurality of source/drain via contacts VA may be in contact with the source/drain contact CA through the upper insulating structure 180. Each of the plurality of source/drain regions 130 may be electrically connected to the source/drain via contact VA through the metal silicide layer 172 and the source/drain contact CA. A bottom surface of each of the plurality of source/drain via contacts VA may be in contact with a top surface of the source/drain contact CA. Each of the plurality of source/drain via contacts VA may include Mo or W. However, the present disclosure is not limited thereto.

In some implementations, a top surface of each of the upper insulating structure 180 and the plurality of source/drain via contacts VA may be covered with an upper insulating layer 192. A constituent material of the upper insulating layer 192 is substantially the same as described above for the constituent material of the interlayer insulating layer 184.

In some implementations, a plurality of upper wiring layers M1 may be arranged through the upper insulating layer 192. Each of the plurality of upper wiring layers M1 may be electrically connected to one source/drain via contact VA selected from the plurality of source/drain via contacts VA thereunder. The plurality of upper wiring layers M1 may include Mo, Cu, W, Co, Ru, Mn, Ti, Ta, Al, a combination thereof, or an alloy thereof. However, the present disclosure is not limited thereto.

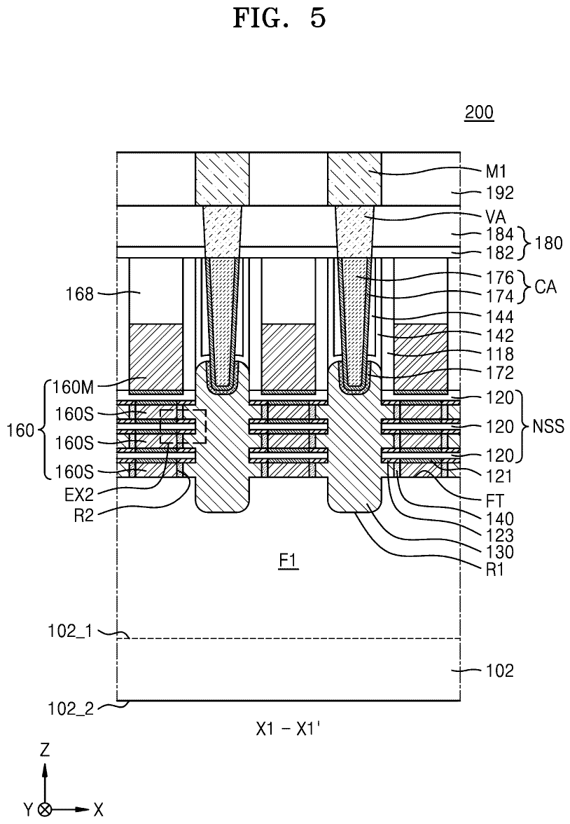

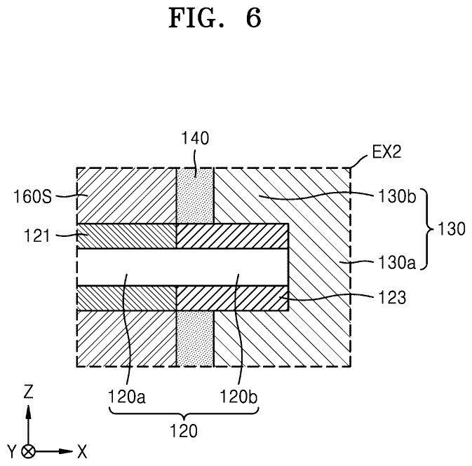

FIG. 5 is a view illustrating an example of a region corresponding to a cross-section taken along the line X1-X1′ of FIG. 1, and is a cross-sectional view for describing an example of an integrated circuit device 200. FIG. 6 is an enlarged cross-sectional view of an example of a region EX2 of FIG. 5.

Because the integrated circuit device 200 of FIGS. 5 and 6 is configured similarly to the integrated circuit device 100 described with reference to FIGS. 1 to 4, a description of common portions with the integrated circuit device 100 described with reference to FIGS. 1 to 4 will be omitted, and a description will focus on the differences.

In some implementations, the integrated circuit device 200 of the present disclosure may include a plurality of first channel layers 120 and a plurality of second channel layers 123. Each of the plurality of first channel layers 120 and the plurality of second channel layers 123 may include TMD. The plurality of second channel layers 123 may cover top and bottom surfaces of the first channel layer 120. That is, the integrated circuit device 200 may include a channel layer having a multilayer structure.

In some implementations, each of the plurality of first channel layers 120 may include a channel portion 120a and an extension portion 120b. The channel portion 120a may extend in the first horizontal direction (X direction) and may be surrounded by the gate line 160. The extension portion 120b may extend from both ends of the channel portion 120a in the first horizontal direction (X direction) to be in contact with a source/drain region 130.

In some implementations, an oxide layer 121 may be between the plurality of first channel layers 120 and the gate line 160. Specifically, the oxide layer 121 may be between the channel portion 120a of the first channel layer 120 and the gate line 160. The oxide layer 121 may surround the channel portion 120a. The oxide layer 121 may surround all sides of the channel portion 120a. For example, the oxide layer 121 may cover top and bottom surfaces and sidewalls in the second horizontal direction (Y direction) of the channel portion 120a, and may extend in the first horizontal direction (X direction).

In some implementations, the oxide layer 121 may include high dielectric constant (high-k) oxide. For example, the oxide layer 121 may include oxide including a transition metal that is different from that of the first channel layer 120. For example, when the first channel layer 120 includes molybdenum disulfide (MoS₂), the oxide layer 121 may include HfO₂. However, the present disclosure is not limited thereto. At this time, the channel 120a and the extension 120b of the first channel layer 120 may include the same material. For example, the channel 120a and the extension 120b may include MoS₂.

In some implementations, the second channel layer 123 may include TMD that is different from that of the first channel layer 120. At this time, the oxide layer 121 may include oxide including the same transition metal as the second channel layer 123. For example, when the first channel layer 120 includes MoS₂, the second channel layer 123 may include HfS₂, and the oxide layer 121 may include HfO₂. However, the present disclosure is not limited thereto. For example, when the first channel layer 120 includes MoS₂, the second channel layer 123 may include zirconium disulfide (ZrS₂), and the oxide layer 121 may include zirconium dioxide (ZrO₂). However, the present disclosure is not limited thereto.

In some implementations, when the second channel layer 123 includes Nb, V, and Ta, and the first channel layer 120 includes Mo, the second channel layer 123 may serve to dope the first channel layer 120. For example, when the second channel layer 123 includes niobium disulfide (NbS₂) and the first channel layer 120 includes MoS₂, the first channel layer 120 may be doped with Nb.

In some implementations, the plurality of second channel layers 123 may cover top and bottom surfaces of the extension 120b. One surface of the second channel layer 123 may be in contact with the source/drain region 130, and the other surface opposite to the one surface may be in contact with the extension 120b of the first channel layer 120. For example, in the case of the second channel layer 123 arranged on a top surface of the extension 120b, part of a top surface may be in contact with the source/drain region 130, and a bottom surface may be in contact with the extension 120b. In addition, in the case of the second channel layer 123 arranged on a bottom surface of the extension 120b, part of a bottom surface may be in contact with the source/drain region 130, and a top surface may be in contact with the extension 120b.

In some implementations, the second channel layer 123 may extend in the first horizontal direction (X direction). The second channel layer 123 may be in contact with the oxide layer 121 and the source/drain region 130. In the first horizontal direction (X direction), the oxide layer 121 and the source/drain region 130 may be apart from each other with the second channel layer 123 therebetween.

Although it is illustrated in FIG. 6 that thicknesses of the oxide layer 121 and the second channel layer 123 in the vertical direction (Z direction) are the same, the present disclosure is not limited thereto. In some implementations, a thickness of the oxide layer 121 in the vertical direction (Z direction) may be less than a thickness of the second channel layer 123 in the vertical direction (Z direction). In addition, a thickness of the oxide layer 121 in the vertical direction (Z direction) may be greater than a thickness of the second channel layer 123 in the vertical direction (Z direction).

In some implementations, a thickness of the channel 120a in the vertical direction (Z direction) may be less than the sum of thicknesses of the extension 120b and the second channel layer 123 in contact with the extension 120b in the vertical direction (Z direction). In addition, the sum of thicknesses of the channel 120a and the oxide layer 121 in contact with the channel 120a in the vertical direction (Z direction) may be substantially equal to the sum of thicknesses of the extension 120b and the second channel layer 123 in contact with the extension portion 120b in the vertical direction (Z direction).

In some implementations, one surface of the oxide layer 121 may be in contact with the gate line 160, and the other surface opposite to the one surface may be in contact with the channel portion 120a of the first channel layer 120. For example, in the case of the oxide layer 121 arranged on a top surface of the channel portion 120a, a top surface may be in contact with the gate line 160 and a bottom surface may be in contact with the channel portion 120a. In addition, in the case of the oxide layer 121 arranged on a bottom surface of the channel portion 120a, a bottom surface may be in contact with the gate line 160 and a top surface may be in contact with the channel portion 120a.

In some implementations, an interface between the gate line 160 and the oxide layer 121 may be coplanar with one surface of the second channel layer 123. For example, in the case of the oxide layer 121 arranged on the top surface of the channel portion 120a, the interface between the gate line 160 and the oxide layer 121 may be coplanar with a top surface of the second channel layer 123. In addition, in the case of the oxide layer 121 arranged on the bottom surface of the channel portion 120a, the interface between the gate line 160 and the oxide layer 121 may be coplanar with a bottom surface of the second channel layer 123.

In the case of an integrated circuit device according to a comparative example, an insulating layer may be formed between the gate line and an internal spacer. In addition, the integrated circuit device 200 of the present disclosure may form the oxide layer 121 only at the interface between the channel layer 120 and the gate line 160, thereby reducing the area of an unnecessary insulating layer and reducing parasitic capacitance. Accordingly, electrical characteristics of the integrated circuit device 200 may be improved.

In addition, because the second channel layer 123 includes TMD that is different from the first channel layer 120, the thicknesses and constituent materials of the first channel layer 120 and the second channel layer 123 may be adjusted to lower resistance of a portion in contact with the source/drain region 130. In addition, when the first channel layer 120 is doped with Nb, the electrical characteristics of the integrated circuit device 200 may be improved because the moving speed of charge carriers increases due to high conductivity.

In some implementations, each of the plurality of gate lines 160 may include a main gate 160M and a plurality of sub-gates 160S. The main gate 160M may cover a top surface of the nanosheet stack NSS and may extend in the second horizontal direction (Y direction). The plurality of sub-gates 160S may be integrally connected to the main gate 160M, and may be arranged among the plurality of channel layers 120, respectively, and between the lowermost channel layer 120 and the active region F1. In the vertical direction (Z direction), a thickness of each of the plurality of sub-gates 160S may be less than a thickness of the main gate 160M.

In some implementations, the plurality of source/drain regions 130 may be arranged among the plurality of gate lines 160, respectively. Each of the plurality of source/drain regions 130 may be arranged adjacent to at least one gate line 160 selected from the plurality of gate lines 160. Each of the plurality of source/drain regions 130 may have surfaces facing first and second channel layers 120 and 132 adjacent thereto.

In some implementations, a plurality of internal spacers 140 may be between the plurality of sub-gates 160S and the plurality of source/drain regions 130, respectively. One sidewall of the internal spacer 140 may be in contact with the sub-gate 160S, and the other sidewall opposite to the one sidewall may be in contact with the source/drain region 130. In addition, top and bottom surfaces of the internal spacer 140 may each be in contact with the second channel layer 123. The plurality of internal spacers 140 may cover sidewalls in the first horizontal direction (X direction) of the sub-gate 160S. Specifically, the pair of internal spacers 140 may be apart from each other in the first horizontal direction (X direction) with the sub-gate 160S therebetween. At this time, the internal spacer 140 may include silicon nitride, silicon oxide, SiCN, SiBN, SiON, SiOCN, SiBCN, SiOC, or a combination thereof.

In some implementations, each of the plurality of source/drain regions 130 may include a central portion 130a and a protrusion 130b. The central portion 130a may be in contact with the surface of each of the plurality of first channel layers 120 and the plurality of second channel layers 123 included in each of the plurality of nanosheet stacks NSS. Specifically, the central portion 130a may be in contact with sidewalls of the extension portion 120b of the first channel layer 120 and the second channel layer 123. The protrusion 130b may extend from the central portion 130a toward the sub-gate 160S. Specifically, the protrusion 130b may be in contact with the sidewall of the internal spacer 140. The protrusion 130b may be apart from the sub-gate 160S with the internal spacer 140 therebetween.

In some implementations, the plurality of protrusions 130b may overlap the plurality of sub-gates 160S in the first horizontal direction (X direction). In addition, top and bottom surfaces of the plurality of protrusions 130b may be in contact with top and bottom surfaces of the plurality of second channel layers 123, respectively. The plurality of protrusions 130b, the plurality of extensions 120b, and the plurality of second channel layers 123 may overlap in the vertical direction (Z direction).

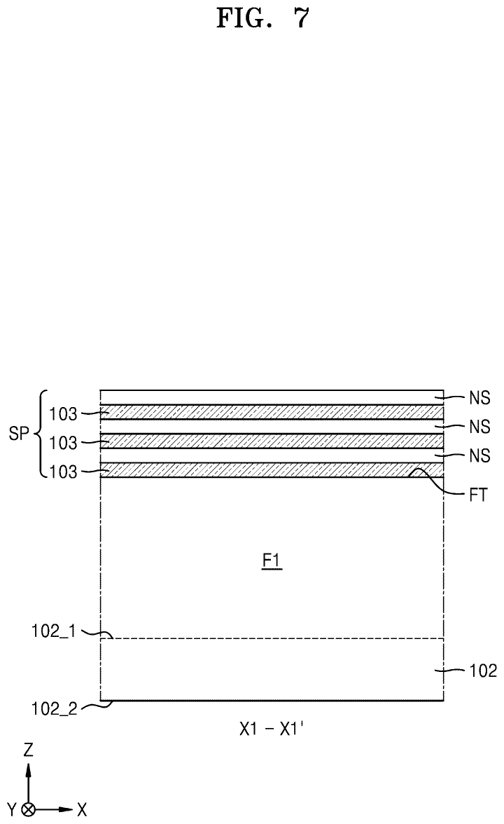

FIGS. 7, 8, 9, 10, 11, 12, 13, 14, 15, 16, and 17 are cross-sectional views illustrating an example of a method of manufacturing an integrated circuit device 100. A method of manufacturing the integrated circuit device 100 described with reference to FIGS. 1 to 4 will be described with reference to FIGS. 7 to 17, and the same reference numerals as in FIGS. 1 to 4 denote the same members, and a detailed description thereof will be omitted.

Referring to FIG. 7, the stacked structure SS in which the plurality of sacrificial semiconductor layers 103 and the plurality of nanosheet semiconductor layers NS are alternately stacked one by one may be formed on the substrate 102. The plurality of nanosheet semiconductor layers NS may have a monolayer structure or a multilayer structure. The plurality of sacrificial semiconductor layers 103 and the plurality of nanosheet semiconductor layers NS may be alternately deposited.

In some implementations, the plurality of sacrificial semiconductor layers 103 and the plurality of nanosheet semiconductor layers NS may include semiconductor materials with different etch selectivities. The plurality of nanosheet semiconductor layers NS may include TMD, and the plurality of sacrificial semiconductor layers 103 may include silicon nitride. However, the t he present disclosure is not limited thereto.

In some implementations, the substrate 102 may include a semiconductor element such as Si or Ge, or a compound semiconductor such as SiGe, SiC, GaAs, InAs, InGaAs, or InP.

Thereafter, the sacrificial semiconductor layer 103, the plurality of nanosheet semiconductor layers NS, and a portion of the substrate 102 may be etched to form the plurality of active regions F1 extending in the first horizontal direction (X direction) on the substrate 102. As a result, a first surface 102_1 of the substrate 102 may be formed and the plurality of active regions F1 may be arranged on the first surface 102_1. The stacked structure SS of the plurality of sacrificial semiconductor layers 103 and the plurality of nanosheet semiconductor layers NS may remain on the fin top surface FT of each of the plurality of active regions F1.

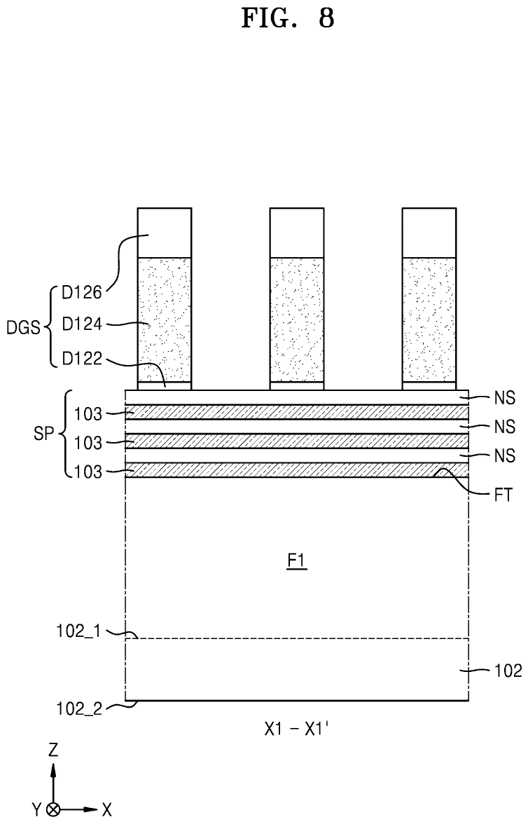

Referring to FIG. 8, a plurality of dummy gate structures DGS may be formed on the stacked structure SS of the plurality of sacrificial semiconductor layers 103 and the plurality of nanosheet semiconductor layers NS.

Each of the plurality of dummy gate structures DGS may extend in the second horizontal direction (Y direction). Each of the plurality of dummy gate structures DGS may have a structure in which an oxide layer D122, a dummy gate layer D124, and a capping layer D126 are sequentially stacked. In some implementations, the dummy gate layer D124 may include polysilicon, and the capping layer D126 may include a silicon nitride layer.

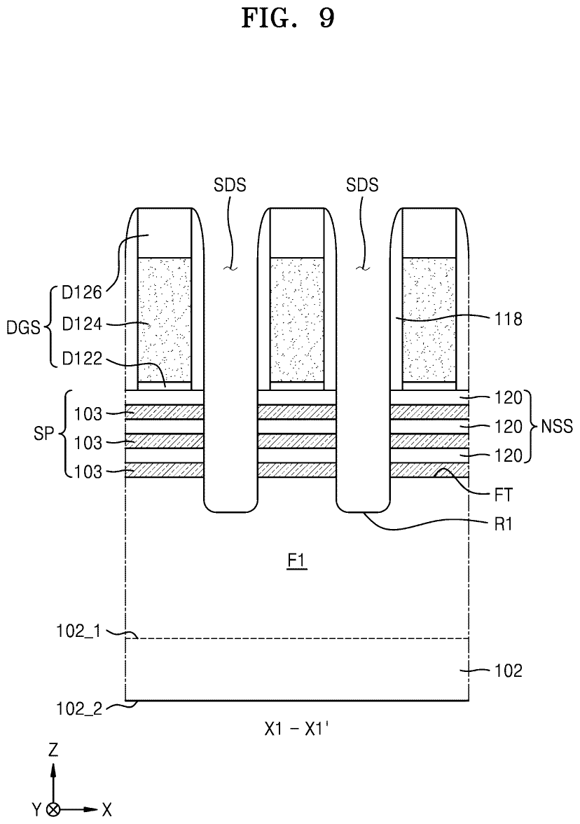

Referring to FIG. 9, after forming a plurality of first insulating spacers 118 covering both sidewalls of each of the plurality of dummy gate structures DGS, some of the plurality of sacrificial semiconductor layers 103 and some of the plurality of nanosheet semiconductor layers NS (refer to FIG. 8) may be etched by using the plurality of dummy gate structures DGS and the plurality of first insulating spacers 118 as etching masks. As a result, each of the plurality of nanosheet semiconductor layers NS may be divided into the plurality of nanosheet stacks NSS each including the plurality of channel layers 120. A stacked pattern SP including the plurality of sacrificial semiconductor layers 103 and the plurality of channel layers 120 may be formed by the etching process.

By the etching process, a plurality of active region recesses R1 and a plurality of source/drain spaces SDS exposing sidewalls of the stacked pattern SP may be formed. In order to form the plurality of active region recesses R1 and the plurality of source/drain spaces SDS, etching may be performed by using dry etching, wet etching, or a combination thereof.

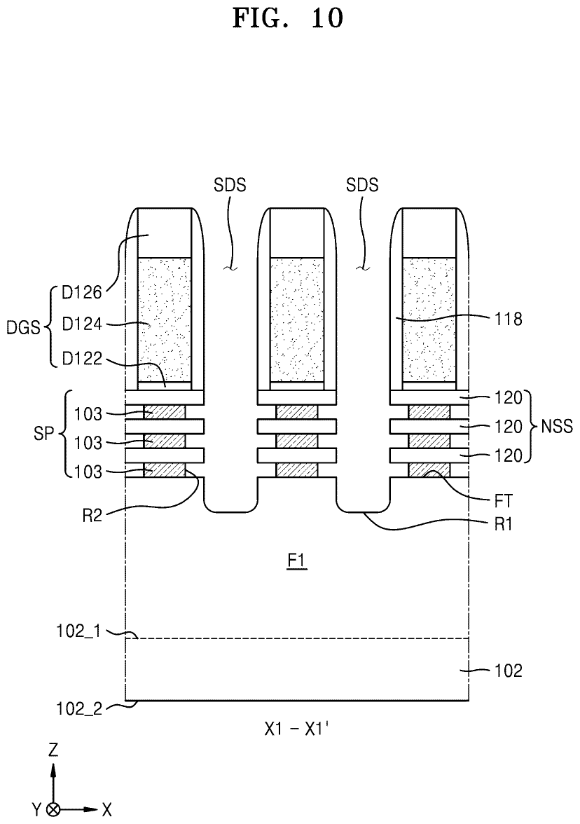

Referring to FIG. 10, part of each of the plurality of sacrificial semiconductor layers 103 of the stacked pattern SP exposed by each of the plurality of source/drain spaces SDS may be removed to form a plurality of side recesses R2. In order to form the plurality of side recesses R2, an etching composition may be applied to the stacked pattern SP through the plurality of source/drain spaces SDS.

In some implementations, by applying the etching composition to the stacked pattern SP, among the plurality of channel layers 120 and the plurality of sacrificial semiconductor layers 103, part of each of the plurality of sacrificial semiconductor layers 103 may be selectively removed.

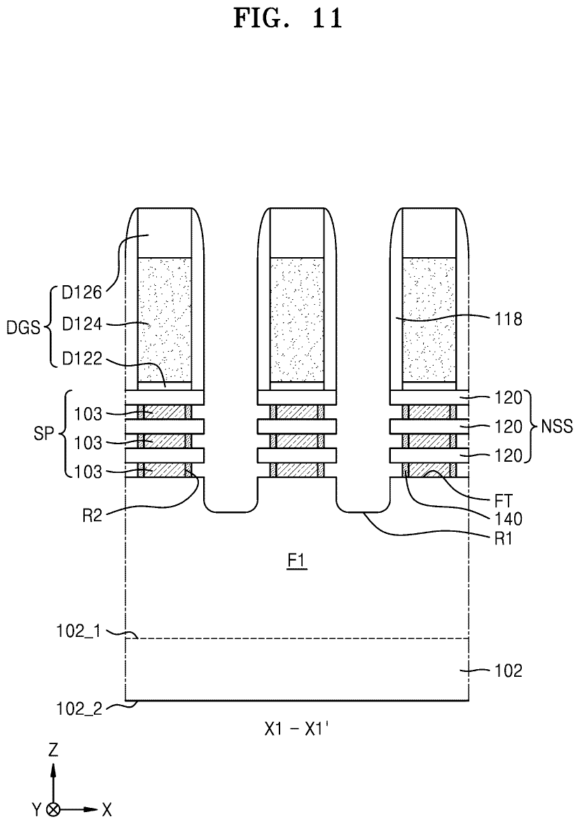

Referring to FIG. 11, the internal spacer 140 may be formed to cover the plurality of side recesses R2. The internal spacer 140 may cover sidewalls in the first horizontal direction (X direction) of the plurality of sacrificial semiconductor layers 103. Specifically, a pair of internal spacers 140 may be apart in the first horizontal direction (X direction) with the sacrificial semiconductor layer 103 therebetween. In addition, the top and bottom surfaces of the internal spacer 140 may be in contact with the channel layer 120. At this time, the internal spacer 140 may include silicon nitride, silicon oxide, SiCN, SiBN, SiON, SiOCN, SiBCN, SiOC, or a combination thereof.

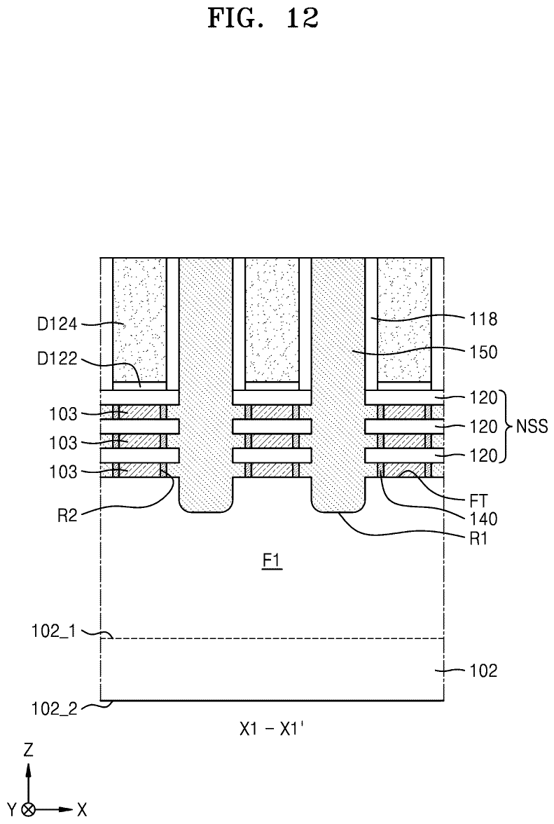

Referring to FIG. 12, an insulating layer 150 may be formed to fill the plurality of active region recesses R1 and the plurality of source/drain spaces SDS. The insulating layer 150 may cover sidewalls of the plurality of internal spacers 140, the plurality of channel layers 120, and the plurality of dummy gate structures DGS (refer to FIG. 11). The insulating layer 150 may include silicon oxide (SiO₂). However, the present disclosure is not limited thereto.

Thereafter, part of the dummy gate layer D124, part of the first insulating spacer 118, part of the insulating layer 150, and the capping layer D126 (refer to FIG. 11) may be removed by a planarization process.

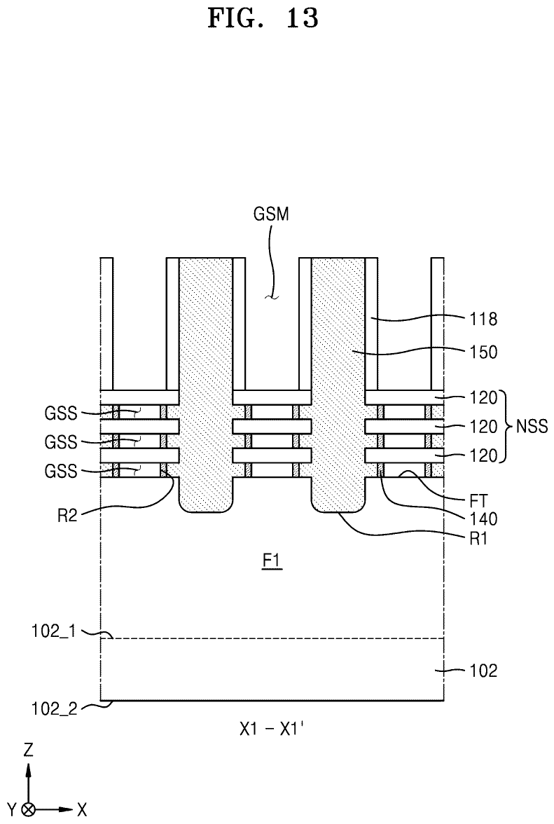

Referring to FIG. 13, a main gate space GSM may be formed by removing the dummy gate layer D124 (refer to FIG. 12) and an oxide layer D122 (refer to FIG. 12) thereunder, and the plurality of nanosheet stacks NSS may be exposed through the main gate space GSM.

Thereafter, the plurality of sacrificial semiconductor layers 103 remaining on the active region F1 may be removed through the main gate space GSM to form a sub-gate space GSS among the plurality of channel layers 120, respectively, and between the lowermost channel layer 120 and the fin top surface FT.

In some implementations, in order to selectively remove the plurality of sacrificial semiconductor layers 103, a difference in etch selectivity between the plurality of channel layers 120 and the plurality of sacrificial semiconductor layers 103 may be used. A liquid or vapor phase etchant may be used to selectively remove the plurality of sacrificial semiconductor layers 103.

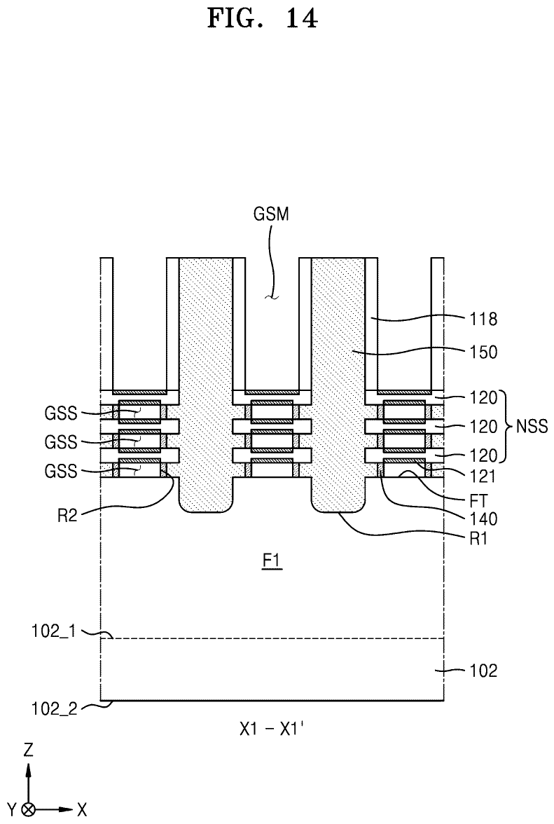

Referring to FIG. 14, the oxide layer 121 may be formed on a surface of the channel layer 120 exposed through the main gate space GSM and the sub-gate space GSS. The oxide layer 121 may be formed on the surface of the channel layer 120 through plasma, and the remaining portion may constitute the channel portion 120a (refer to FIG. 3). For example, the oxide layer 121 may cover top and bottom surfaces and sidewalls in the second horizontal direction (Y direction) of the channel portion 120a and may extend in the first horizontal direction (X).

At this time, when a multi-layered channel layer such as the integrated circuit device 200 of FIGS. 5 and 6 is included, only the top and bottom channel layers (for example, the second channel layer 123 (refer to FIG. 5)) exposed through the main gate space GSM and the sub-gate space GSS may be oxidized to form the oxide layer 121.

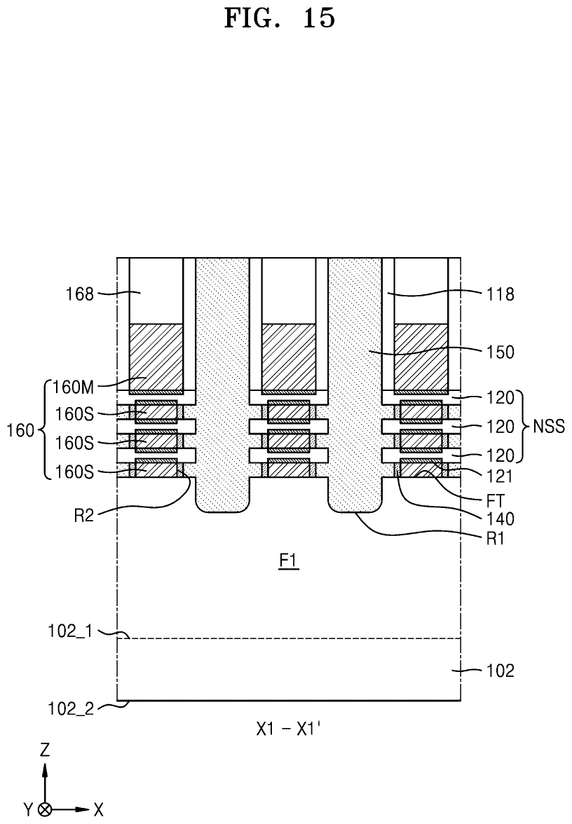

Referring to FIG. 15, the gate line 160 may be formed to fill the main gate space GSM (refer to FIG. 14) and the sub-gate space GSS (refer to FIG. 14). The gate line 160 may include a metal, metal nitride, metal carbide, or a combination thereof. An atomic layer deposition (ALD) process or a chemical vapor deposition (CVD) process may be used to form the gate line 160. The gate line 160 may be apart from the channel layer 120 with the oxide layer 121 therebetween.

Thereafter, part of a top surface of each of the plurality of gate lines 160 may be removed to reduce a height of each of the plurality of gate lines 160, and the plurality of capping insulation patterns 168 may be formed to cover the top surfaces of the plurality of gate lines 160.

In the method of manufacturing the integrated circuit device 100 of the present disclosure, the oxide layer 121 may be formed only at the interface between the channel layer 120 and the gate line 160, thereby reducing the area of an unnecessary insulating layer and reducing parasitic capacitance.

In addition, by forming the oxide layer 121 on the surface of the channel layer 120 by the oxidation process, the interface between the oxide layer 121 and the channel layer 120 may be formed uniformly. In addition, by forming the oxide layer 121 on the surface of the channel layer 120 by the oxidation process, the oxide layer 121 can be formed to be thin. Accordingly, electrical characteristics of the integrated circuit device 100 may be improved.

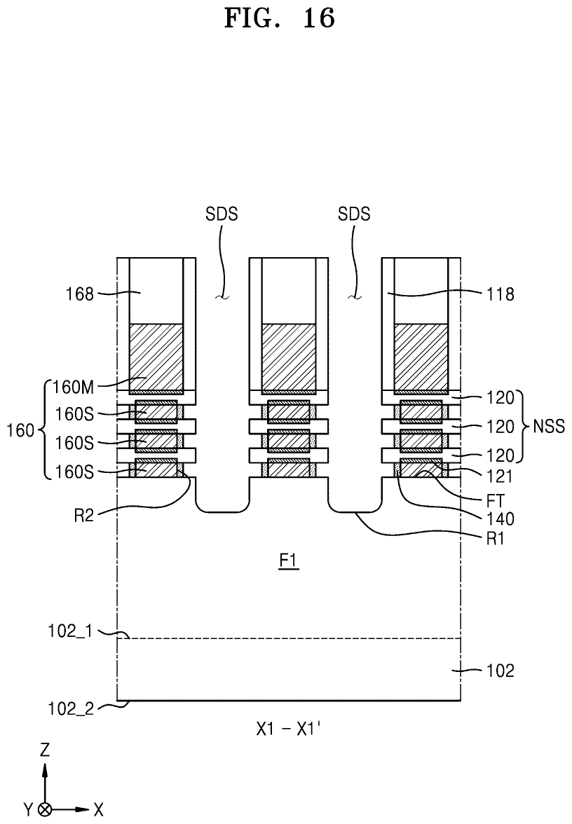

Referring to FIG. 16, the plurality of active region recesses R1 and the plurality of source/drain spaces SDS may be formed again by removing the insulating layer 150. As the insulating layer 150 is removed, the sidewalls of the plurality of internal spacers 140, the plurality of channel layers 120, and sidewalls of the plurality of first insulating spacers 118 may be exposed.

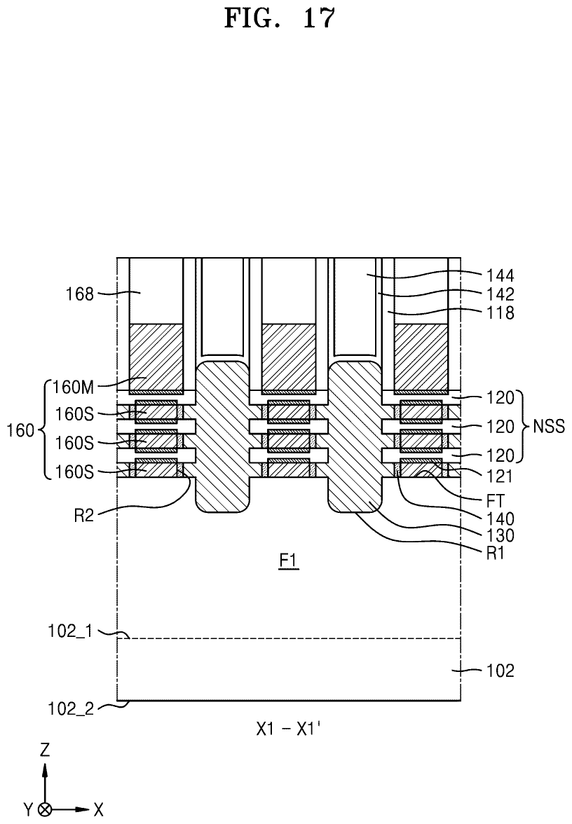

Referring to FIG. 17, the plurality of source/drain regions 130 may be formed on the plurality of active region recesses R1. Thereafter, after forming an insulating liner 142 covering the plurality of source/drain regions 130, and forming an inter-gate insulating layer 144 on the insulating liner 142, a process of planarizing the insulating liner 142 and the inter-gate insulating layer 144 may be performed.

Referring again to FIGS. 2A and 2B, a plurality of source/drain contact holes may be formed through an insulating structure including the insulating liner 142 and the inter-gate insulating layer 144 to expose the plurality of source/drain regions 130. Partial regions of the plurality of source/drain regions 130 may be removed through the plurality of source/drain contact holes by an anisotropic etching process so that the plurality of source/drain contact holes may extend longer toward the substrate 102.

Thereafter, part of the source/drain region 130 exposed by the plurality of source/drain contact holes may be consumed to form the metal silicide layer 172. In some implementations, in order to form the metal silicide layer 172, a metal liner may be formed to conformally cover the exposed surface of the source/drain region 130, and heat treatment may be performed to induce a reaction between the source/drain region 130 and a metal constituting the metal liner. After the metal silicide layer 172 is formed, the remaining portion of the metal liner may be removed. In some implementations, when the metal silicide layer 172 includes a titanium silicide layer, the metal liner may include a Ti layer. The source/drain contact CA including the conductive barrier layer 174 and the contact plug 176 may be formed on the metal silicide layer 172.

Thereafter, the etch stop layer 182 and the interlayer insulating layer 184 covering a top surface of each of the inter-gate insulating layer 144, the plurality of source/drain contacts CA, and the plurality of capping insulation patterns 168 may be sequentially formed to form the upper insulating structure 180, and the plurality of source/drain via contacts VA connected to the plurality of source/drain contacts CA may be formed through the upper insulating structure 180 in the vertical direction (Z direction).

Thereafter, the upper insulating layer 192 may be formed to cover a top surface of each of the upper insulating structure 180 and the plurality of source/drain via contacts VA, and a plurality of upper wiring layers M1 connected to the plurality of source/drain via contacts VA may be formed through the upper insulating layer 192 in the vertical direction (Z direction).

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been shown and described with reference to some implementations thereof, it will be understood that various changes in form and details may be made therein without departing from the spirit and scope of the following claims.

What is claimed is:

1. An integrated circuit device comprising:
an active region extending in a first horizontal direction on a substrate;
a channel layer on the active region and extending in the first horizontal direction, the channel layer being spaced apart from the active region in a vertical direction;
a gate line extending in a second horizontal direction on the active region and surrounding the channel layer, the second horizontal direction intersecting the first horizontal direction;
a source/drain region on the active region, wherein the source/drain region contacts the channel layer; and
an oxide layer between the channel layer and the gate line, wherein the channel layer comprises transition metal dichalcogenides (TMD), and wherein the oxide layer comprises high dielectric constant (high-k) oxide.

2. The integrated circuit device of claim 1, wherein the channel layer and the oxide layer comprise a same transition metal element.

3. The integrated circuit device of claim 1, wherein a transition metal element in the channel layer is different from a transition metal element in the oxide layer.

4. The integrated circuit device of claim 1, wherein the channel layer comprises a channel portion extending in the first horizontal direction and surrounded by the gate line, and an extension portion extending from a first end of the channel portion and from a second end of the channel portion in the first horizontal direction, wherein the extension portion contacts the source/drain region, and
wherein the oxide layer covers a top surface, a bottom surface, and a plurality of sidewalls in the second horizontal direction of the channel portion.

5. The integrated circuit device of claim 4, wherein an interface between the gate line and the oxide layer is coplanar with a top surface or a bottom surface of the extension portion.

6. The integrated circuit device of claim 1, wherein the channel layer comprises a channel portion extending in the first horizontal direction and surrounded by the gate line, and an extension portion extending from a first end of the channel portion and from a second end of the channel portion in the first horizontal direction, wherein the extension portion contacts the source/drain region, and
wherein a thickness in the vertical direction of the channel portion is less than a thickness in the vertical direction of the extension portion.

7. The integrated circuit device of claim 1, wherein the channel layer comprises a channel portion extending in the first horizontal direction and surrounded by the gate line, and an extension portion extending from a first end of the channel portion and from a second end of the channel portion in the first horizontal direction, wherein the extension portion contacts the source/drain region, and
wherein a sum of a thickness in the vertical direction of the channel portion and a thickness in the vertical direction of the oxide layer contacting the channel portion is equal to a thickness in the vertical direction of the extension portion.

8. The integrated circuit device of claim 1, wherein the gate line comprises a plurality of sub-gates between a plurality of channel layers adjacent in the vertical direction and between a lowermost channel layer of the plurality of channel layers and the active region, and the gate line comprises an internal spacer between the plurality of sub-gates and the source/drain region.

9. An integrated circuit device comprising:
an active region extending in a first horizontal direction on a substrate;
a channel layer including a first channel layer and a second channel layer, the first channel layer being on the active region, being spaced apart from the active region in a vertical direction, and extending in the first horizontal direction, and the second channel layer covering a top surface and a bottom surface of the first channel layer;
a gate line extending in a second horizontal direction on the active region and surrounding the channel layer, the second horizontal direction intersecting the first horizontal direction;
a source/drain region on the active region, wherein the source/drain region contacts the channel layer; and
an oxide layer between the channel layer and the gate line, wherein the first channel layer comprises first transition metal dichalcogenides (TMD) including a first transition metal, wherein the second channel layer comprises second TMD including a second transition metal that is different from the first transition metal, and wherein the oxide layer comprises high dielectric constant (high-k) oxide.

10. The integrated circuit device of claim 9, wherein the second channel layer and the oxide layer comprise a same transition metal element.

11. The integrated circuit device of claim 9, wherein the first channel layer comprises a channel portion extending in the first horizontal direction and surrounded by the gate line, and an extension portion extending from a first end of the channel portion and from a second end of the channel portion in the first horizontal direction, wherein the extension portion contacts the source/drain region, and
wherein the oxide layer covers a top surface, a bottom surface, and a plurality of sidewalls in the second horizontal direction of the channel portion.

12. The integrated circuit device of claim 9, wherein the first channel layer comprises a channel portion extending in the first horizontal direction and surrounded by the gate line, and an extension portion extending from a first end of the channel portion and from a second end of the channel portion in the first horizontal direction, wherein the extension portion contacts the source/drain region, and
wherein the second channel layer covers a top surface and a bottom surface of the extension portion.

13. The integrated circuit device of claim 12, wherein an interface between the gate line and the oxide layer is coplanar with a top surface or a bottom surface of the second channel layer.

14. The integrated circuit device of claim 12, wherein a thickness in the vertical direction of the channel portion is less than a sum of a thickness in the vertical direction of the extension portion and a thickness in the vertical direction of the second channel layer.

15. The integrated circuit device of claim 9, wherein the oxide layer and the source/drain region are spaced apart from each other in the first horizontal direction, and the second channel layer is between the oxide layer and the source/drain region.

16. The integrated circuit device of claim 9, wherein the first channel layer is doped with the second channel layer.

17. The integrated circuit device of claim 9, wherein the gate line comprises a plurality of sub-gates between a plurality of channel layers adjacent in the vertical direction and between a lowermost channel layer of the plurality of channel layers and the active region, and the gate line comprises an internal spacer between the plurality of sub-gates and the source/drain region.

18. An integrated circuit device comprising:
an active region extending in a first horizontal direction on a substrate;
a channel layer on the active region and extending in the first horizontal direction, the channel layer being spaced apart from the active region in a vertical direction;
a gate line extending in a second horizontal direction on the active region and surrounding the channel layer, the second horizontal direction intersecting the first horizontal direction, wherein the gate line includes a main gate and a plurality of sub-gates between a plurality of channel layers adjacent in the vertical direction and between a lowermost channel layer of the a plurality of channel layers and the active region, and the main gate is connected to the sub-gates and covers an uppermost channel layer of the a plurality of channel layers;
a source/drain region on the active region contacting the channel layer;
an insulating spacer covering a plurality of sidewalls of the main gate;
an internal spacer between the plurality of sub-gates and the source/drain region; and
an oxide layer between the channel layer and the gate line, wherein the channel layer comprises transition metal dichalcogenides (TMD) including a first transition metal, and wherein the oxide layer comprises high dielectric constant (high-k) oxide including the first transition metal.

19. The integrated circuit device of claim 18, wherein the channel layer comprises a channel portion extending in the first horizontal direction and surrounded by the gate line, and an extension portion extending from a first end the channel portion and from a second end of the channel portion in the first horizontal direction, wherein the extension portion contacts the source/drain region, and
wherein the oxide layer covers a top surface, a bottom surface, and a plurality of sidewalls in the second horizontal direction of the channel portion.

20. The integrated circuit device of claim 18, wherein the channel layer comprises a channel portion extending in the first horizontal direction and surrounded by the gate line, and an extension portion extending from a first end of the channel portion and from a second end of the channel portion in the first horizontal direction, wherein the extension portion contacts the source/drain region, and
wherein a thickness in the vertical direction of the channel portion is less than a thickness in the vertical direction of the extension portion.
